(19) United States
(12) Patent Application Publication
(10) Pub. No.: US 2007/0158779 A1
(43) Pub. Date: Jul. 12, 2007

(54) Methods and semiconductor structures for latch-up suppression using a buried damage layer

(75) Inventors: Ethan Harrison Cannon, Essex Junction, VT (US); Toshiharu Furukawa, Essex Junction, VT (US); Robert J. Gauthier JR., Hinesburg, VT (US); David Vaclav Horak, Essex Junction, VT (US); Jack Allan Mandelman, Flat Rock, NC (US); William Robert Tonti, Essex Junction, VT (US)

Correspondence Address: WOOD, HERRON & EVANS, L.L.P. (IBM), 2700 CAREW TOWER, 441 VINE STREET, CINCINNATI, OH, 45202, US

(73) Assignee: INTERNATIONAL BUSINESS MACHINES CORPORATION, ARMONK, NY (US)

(21) Appl. No.: 11/330,688

(22) Filed: Jan. 12, 2006

(51) Int. Cl. H01L 29/00

(52) U.S. Cl. 257/500

(57) ABSTRACT

Semiconductor structures and methods for suppressing latch-up in bulk CMOS devices. The structure comprises a damage layer formed in a substrate, a first doped well formed in the substrate, and a second doped well formed in the substrate proximate to the first doped well. The damage layer extends within the substrate to intersect the first and second doped wells. The damage layer may be formed by ion implantation followed by growth of an epitaxial layer to segregate the active device regions from the damage layer.

### FIELD OF THE INVENTION

The invention relates generally to semiconductor structures and methods and, in particular, to methods for suppressing latch-up in bulk complementary metal-oxide-semiconductor device structures and semiconductor structures produced by these methods.

### BACKGROUND OF THE INVENTION

Complementary metal-oxide-semiconductor (CMOS) technologies integrate P- and N-channel field effect transistors (FETs) to form an integrated circuit using a semiconductor substrate. Latch-up, which is precipitated by unwanted transistor action of parasitic bipolar transistors inherently present in bulk CMOS devices, may be a significant issue for bulk CMOS technologies. The unwanted parasitic transistor action, which has various triggers, may cause the bulk CMOS device to fail. For outer space based applications, latch-up may be induced by the impingement of high energy ionizing radiation and particles (e.g., cosmic rays, neutrons, protons, alpha particles). Because the integrated circuit cannot be easily replaced in space-based platforms, the chip failure may prove catastrophic. Hence, designing bulk CMOS devices with a high tolerance to latch-up is an important consideration for circuit operation in the natural space radiation environment, as well as military systems and high reliability commercial applications.

Bulk CMOS device designs may be adjusted to suppress latch-up. For example, latch-up may be suppressed in 0.25 micron device technologies by building bulk CMOS devices on epitaxial substrates (e.g., a p-type epitaxial layer on a highly-doped p-type substrate wafer). Highly-doped substrate wafers provide excellent current sinks for latch-up-initiating currents. However, epitaxial substrates are expensive to produce and may increase the design complexity of several critical circuits, such as electrostatic discharge (ESD) protective devices.

Another conventional approach for suppressing latch-up is the use of guard ring diffusions, which have various disadvantages. Guard ring diffusions are costly because they occupy a significant amount of active area silicon real estate. In addition, although guard ring diffusions collect a majority of the minority carriers in the substrate, a significant fraction may escape collection by flowing underneath the guard ring diffusion.

Semiconductor-on-insulator (SOI) substrates are recognized as generally free of latch-up. However, CMOS devices are expensive to fabricate using an SOI substrate, as compared to fabrication using bulk substrates. Furthermore, SOI substrates suffer from various other radiation-induced failure mechanisms aside from latch-up. Another disadvantage is that SOI devices do not generally come with a suite of ASIC books that would enable simple assembly of low-cost designs.

Conventional CMOS devices are susceptible to latch-up generally because of the close proximity of N-channel and P-channel devices. For example, a typical CMOS device fabricated on a p-type substrate includes a P-channel transistor fabricated in an N-well and an N-channel transistor fabricated in a P-well of opposite conductivity type to the N-well. The N- and P-wells are separated by only a short distance and adjoin across a junction. This densely-packed CMOS structure inherently forms a parasitic lateral bipolar (PNP) structure and parasitic vertical bipolar (NPN) structure. Latch-up may occur due to regenerative feedback between these NPN and PNP structures.

With reference to FIG. 1, a portion of a standard triple-well bulk CMOS structure 30(i.e., CMOS inverter) includes a P-channel transistor 10 formed in an N-well 12 of a substrate 11, an N-channel transistor 14 formed in a P-well 16 of the substrate 11 that overlies a buried N-band 18, and a shallow trench isolation (STI) region 20 separating the N-well 12 from the P-well 16. Other STI regions 21 are distributed across the substrate 11. The N-channel transistor 14 includes n-type diffusions representing a source 24 and a drain 25. The P-channel transistor 10 has p-type diffusions representing a source 27 and a drain 28. The N-well 12 is biased at the standard power supply voltage (V_{dd}) and the P-well 16 is coupled to the substrate ground potential. The input of the CMOS structure 30 is connected to a gate 13 of the P-channel transistor 10 and to a gate 15 of the N-channel transistor 14. The output of CMOS structure 30 is connected to the drain 28 of the P-channel transistor 10 and the drain 25 of the N-channel transistor 14. The source 27 of the P-channel transistor 10 is connected to V_{dd} and the source 24 of the N-channel transistor 14 is coupled to ground. Guard ring diffusions 34, 36 encircle the CMOS structure 30.

The n-type diffusions constituting the source 24 and drain 25 of the N-channel transistor 14, the isolated P-well 16, and the underlying N-band 18 constitute the emitter, base, and collector, respectively, of a vertical parasitic NPN structure 22. The p-type diffusions constituting the source 27 and drain 28 of the P-channel transistor 10, the N-well 12, and the isolated P-well 16 constitute the emitter, base, and collector, respectively, of a lateral parasitic PNP structure 26. Because the N-band 18 constitutes the collector of the NPN structure 22 and also the base of the PNP structure 26 and the P-well 16 constitutes the base of the NPN structure 22 and also the collector of the PNP structure 26, the parasitic NPN and PNP structures 22, 26 are wired to result in a positive feedback configuration.

A disturbance, such as impinging ionizing radiation, a voltage overshoot on the source 27 of the P-channel transistor 10, or a voltage undershoot on the source 24 of the N-channel transistor 14, may result in the onset of regenerative action. This results in negative differential resistance behavior and, eventually, latch-up of the bulk CMOS device. In latch-up, an extremely low-impedance path is formed between emitters of the vertical parasitic NPN structure 22 and the lateral parasitic PNP structure 26, as a result of the bipolar bases being flooded with carriers. The low-impedance state may precipitate catastrophic failure of that portion of the integrated circuit. The latched state may only be exited by removal of, or drastic lowering of, the power supply voltage below the holding voltage. Unfortunately, irreversible damage to the integrated circuit may occur almost instantaneously with the onset of the disturbance so that any reaction to exit the latched state is belated.

What is needed, therefore, is a structure and method for modifying standard bulk CMOS device designs that suppresses latch-up, while being cost effective to integrate into the process flow, and that overcomes the disadvantages of conventional bulk CMOS semiconductor structures and methods of manufacturing such semiconductor structures.

### SUMMARY OF THE INVENTION

The present invention is generally directed to semiconductor structures and methods that improve latch-up immunity or suppression in standard bulk CMOS device designs, while retaining cost effectiveness for integration into the process flow forming the P-channel and N-channel field effect transistors characteristic of bulk CMOS devices. In accordance with an embodiment of the present invention, a semiconductor structure comprises a first doped well formed in a substrate and a second doped well formed in the substrate proximate to the first doped well. A damage layer extends within the substrate to intersect the first and second doped wells. The damage layer operates to suppress latch-up of bulk CMOS devices built using the semiconductor structure.

In another aspect of the present invention, a method is provided for fabricating a semiconductor structure in a substrate of monocrystalline semiconductor material. The method comprises forming a damage layer of non-monocrystalline semiconductor material buried beneath a top surface of the substrate. A first doped well is formed that extends to a first depth in the substrate that intersects the damage layer. A second doped well is formed that extends to a second depth in the substrate that also intersects the damage layer.

### BRIEF DESCRIPTION OF THE DRAWINGS

The accompanying drawings, which are incorporated in and constitute a part of this specification, illustrate embodiments of the invention and, together with a general description of the invention given above and the detailed description of the embodiments given below, serve to explain the principles of the invention.

FIG. 1 is a diagrammatic view of a portion of a substrate with a bulk CMOS device constructed in accordance with the prior art.

FIGS. 2-5 are diagrammatic views of a portion of a substrate at various fabrication stages of a processing method in accordance with an embodiment of the present invention.

FIGS. 6-8 are diagrammatic views of a portion of a substrate at a fabrication stage of a processing method in accordance with alternative embodiments of the present invention.

### DETAILED DESCRIPTION

The present invention provides a buried damage layer of controlled crystalline defects formed in the base regions (N-well and P-well) of dual-well and triple-well bulk CMOS devices. The buried damage layer limits the effect of the vertical parasitic NPN structure and the lateral parasitic PNP structure responsible for latch-up in such bulk CMOS devices. The invention is advantageously implemented in the context of bulk CMOS devices where pairs of N-channel and P-channel field effect transistors are formed adjacent to each other in a P-well and an N-well, respectively, and the P-well is isolated from the N-well by a shallow trench isolation (STI) region. In a triple-well structure, the damage region may be formed through the N-well and N-band with minimal encroachment upon the junction between the N-well and P-well, which is believed to degrade the gain of the lateral parasitic PNP structure 26 (FIG. 1) while maintaining low-leakage characteristics. The buried damage layer of the present invention is believed to promote rapid carrier recombination by shortening the minority carrier lifetime, which suppresses latch-up. Thus, the gain of the parasitic NPN and PNP structures 22, 26 (FIG. 1) is reduced to the point where latch-up, if initiated, is not sustained. The present invention will now be described in greater detail by referring to the drawings that accompany the present application.

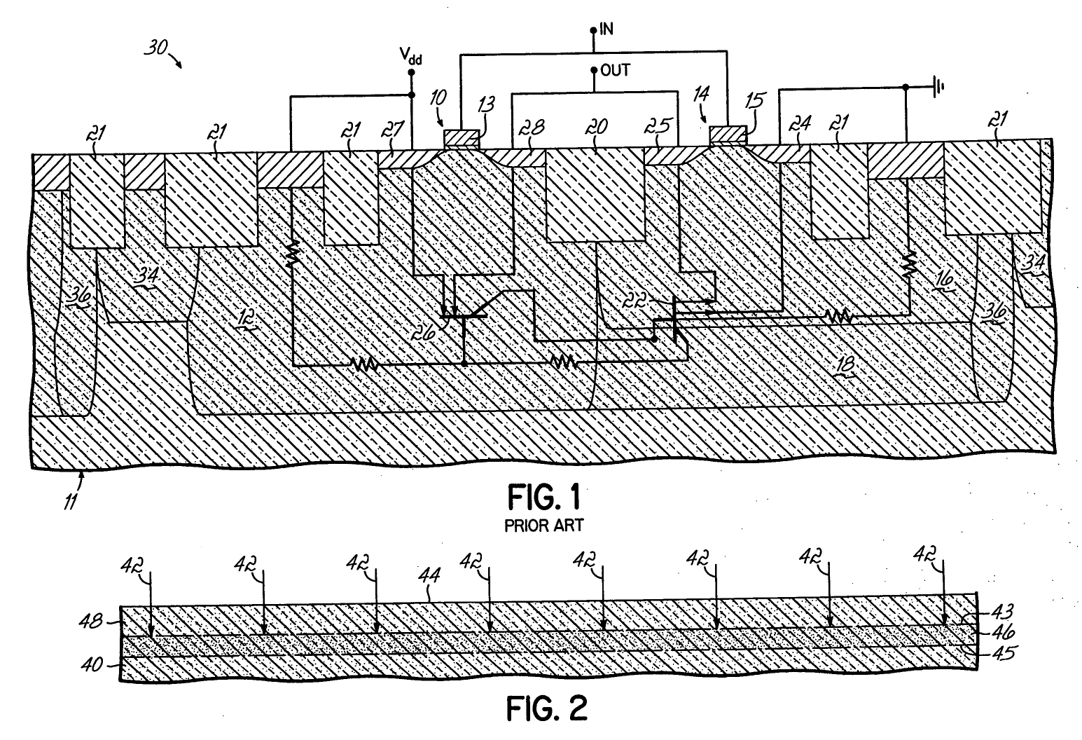

With reference to FIG. 2, a bulk substrate 40, which may be a bulk monocrystalline silicon substrate typically having a substantially uniform P-type doping concentration between 5×10¹⁵ cm⁻³ to 1×10¹⁷ cm⁻³, is obtained and ion implanted with a damaging atomic species. Specifically, energetic ions, as indicated diagrammatically by singled-headed arrows 42, are introduced by an ion implantation process into the substrate 40 to introduce a crystalline damage layer 46. The energetic ions 42, which are generated from a source gas, are directed to impinge a top surface 44 of the substrate 40 at normal or near-normal incidence, although the invention is not so limited. The ions 42 may be implanted with the substrate 40 at or near room or ambient temperature, although the present invention is not so limited.

As the ions 42 penetrate the substrate 40, the ions 42 lose energy via scattering events with atoms and electrons in the semiconductor material constituting substrate 40. The particular energy loss mechanism is a function of the kinetic energy of the ions 42 with electronic interaction prevailing at high energy and nuclear stopping dominating at low energies. Energy lost by the ions 42 in electronic interactions is subsequently transferred to phonons, which heats the constituent semiconductor material of the substrate 40 but produces no permanent damage. Energy lost in nuclear collisions displaces target atoms of the substrate 40 from their original lattice sites and permanently damages the substrate 40. As the ions 42 slow down with increasing penetration depth, nuclear stopping increases in importance. When each individual ion 42 collides with a target atom of the substrate 40, a recoil cascade is initiated that dissipates the transferred kinetic energy by collisions with other target atoms. The recoil cascade generates vacancies and interstitial atoms in the lattice structure of substrate 40 and interstitial target atoms dispersed among the atoms in the lattice structure remaining on regular lattice sites.

The ions 42 eventually lose all of their initial kinetic energy and stop in the substrate 40 to produce a damage band or layer 46. The damage layer 46 coincides approximately with the depth profile of the stopped ions 42 and extends horizontally in a plane substantially parallel to a top surface of substrate 40. Similar to the stopped ions 42, the damage layer 46 is characterized by a depth profile distributed with a range straggle about a projected range, which is measured as a perpendicular distance of the damage peak from the top surface 44. Essentially all of the implanted ions 42 come to rest within a distance of three times the range straggle from the projected range, which implies that the damage has a similar distribution. After the ion implantation is concluded, uncombined vacancies and interstitial atoms remain and are distributed across the thickness of the damage layer 46.

The damage layer 46 is significantly damaged, and may be substantially non-monocrystalline or amorphous, to precipitate a loss of long-range order because of the energy-loss dynamics of the implantation process. The damage layer 46 is buried beneath an upper crystalline layer 48, which is located vertically between the top surface 44 and the damage layer 46, and is generally bounded between first and second horizontal levels or penetration depths 43, 45 in substrate 40 measured perpendicular to top surface 44. The penetration depths 43, 45 are generally parallel to the top surface 44. In the damage layer 46, the ions 42 have enough energy per nuclear collision to displace atoms of the substrate 40 from their lattice sites and cause displacement damage. The damage layer 46 is implanted at a depth and with a kinetic energy sufficient to reduce substrate/well resistance and, thereby, inhibit parasitic transistor action by operating as a high density of recombination centers for minority carriers.

The ions 42 may originate from a source gas selected to provide, when ionized and accelerated to impart kinetic energy, neutral impurities in silicon like nitrogen (N), oxygen (0), carbon (C), gold (Au), platinum (Pt), germanium (Ge), and silicon (Si), n-type impurities in silicon like arsenic (As), p-type impurities in silicon like boron (BF₂), and other elements capable of inducing lattice damage. Advantageously, the ions 42 are selected from neutral and n-type impurities, if the substrate 40 is silicon, for triple-well structures.

A shallow implant depth is preferred in order to provide a tight range straggle and avoid damage to the upper crystalline layer 48 of the substrate 40, which will participate in forming active device regions. Light damage in the upper crystalline layer 48 may be caused, for example, by electronic collisions between atoms of the substrate 40 and the implanted ions 42. However, the semiconductor material of the substrate 40 proximate to top surface 44 remains crystalline to an extent sufficient to promote epitaxy during subsequent fabrication stages.

The ion dose is preferably selected such that the peak atomic concentration of the implanted ions 42 in the damage layer 46 exceeds the solid solubility of the impurity in the constituent material of the substrate 40. By exceeding the solid solubility, subsequent heated process steps do not anneal the crystalline defects in the damage layer 46. Advantageously, the peak atomic concentration for the implanted ions 42 in damage layer 46 may be in the range of 5×10¹⁹ cm⁻³ to 5×10²¹ cm⁻³ and, in certain embodiments, may be as low as 5×10¹⁸ cm⁻³ to provide the requisite crystalline damage. For example, a suitable dose of implanted O⁺may range from 1×10¹⁴ cm⁻² to 5×10¹⁶ cm⁻² at a kinetic energy between about 10 keV and about 50 keV, although the invention is not so limited. The present invention contemplates other implant conditions, i.e., energy and dose, that are capable of forming damage layer 46 in substrate 40. The ions 42 are implanted across the top surface 44 of the entire substrate 40, although certain regions of substrate 40 may be optionally protected by a block mask during implantation.

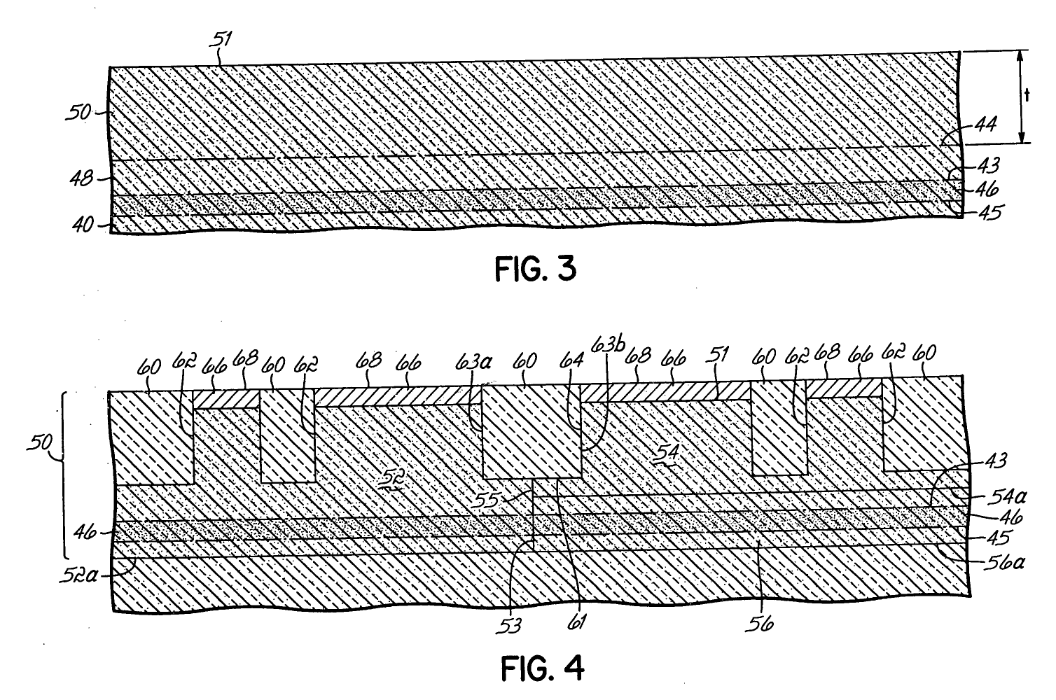

With reference to FIG. 3 in which like reference numerals refer to like features in FIG. 2 and at a subsequent fabrication stage, an epitaxial layer 50 of a semiconductor material, such as silicon, is grown on the top surface 44 of the substrate 40 by an epitaxial growth process that relies on the upper crystalline layer 48 as a growth template. For example, silicon constituting the epitaxial layer 50 may be deposited by a chemical vapor deposition (CVD) process using a silicon source gas (e.g., silane). The growth conditions are such that the epitaxial layer 50 incorporates few defects from the substrate 40. The epitaxial layer 50 has a top surface 51 that overlies the damage layer 46 and a thickness, t, measured perpendicular to top surface 51 from top surface 51 to the former top surface 44 of substrate 40. The epitaxial layer 50 may be lightly doped with 5×10¹⁵ cm⁻³ to 1×10¹⁷ cm⁻³ of a p-type dopant, such as boron, by in situ doping during deposition. The epitaxial layer 50 comprises an integral portion of the substrate 40 that shares a crystalline structure with upper crystalline layer 48. For simplicity, the description below may refer to the substrate 40 with the understanding that the epitaxial layer 50 is an integral component of a monolithic body consisting of the epitaxial layer 50 and the substrate 40 before the addition of the epitaxial layer 50.

With reference to FIG. 4 in which like reference numerals refer to like features in FIG. 3 and at a subsequent fabrication stage, standard bulk CMOS processing follows, which includes forming shallow trench isolation (STI) regions 60 in the substrate 40 by, for example, a conventional patterning, etch, fill, and planarization process characteristic of standard bulk CMOS processing. The STI regions 60 are formed using a patterned hard mask 66 that bears a shallow trench pattern imparted by a conventional photolithography and etching process. Specifically, the shallow trench pattern may be created in hard mask 66 by applying a photoresist (not shown) on the hard mask 66, exposing the photoresist to a pattern of radiation to create a latent shallow trench pattern in the photoresist, developing the latent shallow trench pattern in the exposed photoresist, transferring the shallow trench pattern from the photoresist into the hard mask 66 with an anisotropic etching process, and stripping the photoresist to expose a top surface 68 of the hard mask 66.

The shallow trench pattern is then transferred from the patterned hard mask 66 into the underlying epitaxial layer 50 as trenches 62, 64 with an anisotropic dry etching process. The hard mask 66 may be composed of, for example, silicon nitride deposited using a low-pressure CVD or plasma-enhanced CVD process, that is patterned using an etch chemistry that removes silicon nitride selective to the material constituting the epitaxial layer 50. A pad stack (not shown) may be provided between the epitaxial layer 50 and hard mask 66 and etched to perpetuate the penetration in depth of the shallow trench pattern to top surface 51. The anisotropic dry etching process may be constituted by, for example, reactive-ion etching, ion beam etching, or plasma etching. The shallow trench pattern in the epitaxial layer 50 is filled by amounts of a dielectric material, such as tetraethylorthosilicate (TEOS) or a high-density-plasma (HDP) oxide, deposited across the top surface 68 of hard mask 66 and planarized by, for example, a conventional chemical mechanical planarization (CMP) process to be coplanar with the top surface 68 of the hard mask 66.

After the hard mask 66 is stripped, a triple-well structure is then formed that consists of an N-well 52, a P-well 54, and a deep buried N-well or N-band 56 in the substrate 40. The buried N-band 56 supplies electrical isolation for the P-well 54. This triple-well construction permits the optimization of bias potentials for both N- and P-wells 52, 54. The N-well 52 and P-well 54 meet or converge to share a boundary (i.e., are coextensive) along a well junction or interface 55 that defines a p-n junction. Similarly, the N-well 52 and N-band 56 meet or converge to share a boundary along an interface 53.

The N-band 56, as well as other N-bands (not shown) dispersed across the substrate 40, are formed by patterning another mask layer (not shown) on top surface 51 and implanting an appropriate n-conductivity type impurity into the substrate 40 in this set of unmasked regions. The N-well 52, as well as other N-wells (not shown) dispersed across the substrate 40, are likewise formed by patterning a mask layer (not shown), such as a photoresist, applied on the top surface 51 with techniques known in the art and implanting an appropriate n-conductivity type impurity into the substrate 40 in unmasked regions. The P-well 54, as well as other P-wells (not shown) dispersed across the substrate 40, are likewise formed by patterning another mask layer (not shown) applied on top surface 51 and implanting an appropriate p-conductivity type impurity into the substrate 40 in this set of unmasked regions. Typically, the P-well 54 is formed by counterdoping the N-band 56 and has an opposite conductivity type from the N-well 52 and N-band 56. Generally, the dopant concentration in the N-well 52 ranges from about 5.0×10¹⁷ cm⁻³ to about 7.0×10¹⁸ cm⁻³, the dopant concentration in the P-well 54 ranges from about 5.0×10¹⁷ cm⁻³ to about 7.0×10¹⁸ cm⁻³, and the dopant concentration in the N-band 56 ranges from about 5.0×10¹⁷ cm⁻³ to about 7.0×10¹⁸ cm⁻³. A thermal anneal may be required to electrically activate the implanted impurities operating as the p-type and n-type dopants.

The actual depth of the damage layer 46, and its location with respect to the bottom of the STI regions 60 and the interface 55, is adjusted by adjusting the thickness of the epitaxial layer 50 and the kinetic energy and species of the implanted ions 42 forming damage layer 46. The thickness of the epitaxial layer 50 is selected such that the damage layer 46 intersects and extends through the N-well 52 and N-band 56 and such that the shallowest penetration depth 43 of the damage layer 46 is deeper in the substrate 40 than the bottoms of the STI regions 60 in trenches 62 and a base 61 of STI region 60 in trench 60. Advantageously, the damage layer 46 does not extend through the junction 55 between the N-well 52 and P-well 54 so that the characteristics of junction 55 are unaffected. The N-well 52 has a boundary 52a that is deeper than the deepest penetration depth 45 of the damage layer 46. Similarly, the N-band 56 has a boundary 56a that is deeper than the deepest penetration depth 45 of the damage layer 46. The P-well 54 has a boundary 54a that borders the N-band 56.

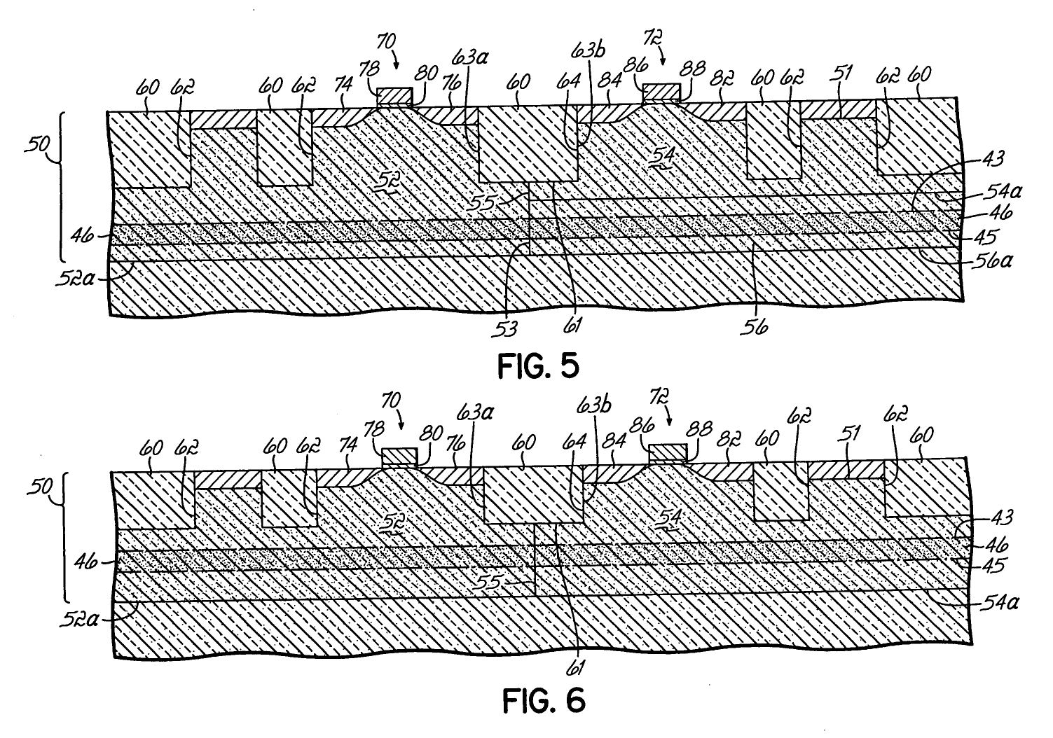

With reference to FIG. 5 in which like reference numerals refer to like features in FIG. 4 and at a subsequent fabrication stage, the patterned hard mask 66 and interstitial portions of the dielectric material are removed by, for example, one or more CMP processes to define the final appearance of the STI regions 60, which provide lateral electrical isolation between adjacent partitioned regions of the epitaxial layer 50. In particular, the STI region 60 situated in trench 64 electrically isolates the N-well 52 from the P-well 54, but has base 61 that is at a depth separated by a vertical gap from the top depth of the N-band 56 and the boundary 54a of the P-well 54 so that junction 55 is present at the intersection between the N-well 52 and P-well 54. The STI region 60 in trench 64 also has sidewalls 63a, 63b that extend from the base 61 to the top surface 51. Sidewall 63a abuts the N-well 52 and sidewall 63b abuts the P-well 54. The top surface 51 of epitaxial layer 50 is recessed by the process defining the final appearance of the STI regions 60, which effectively moves the top surface 51 closer to the damage layer 46.

A P-channel transistor 70 is built using the N-well 52 and an N-channel transistor 72 is built using the P-well 54 to define a bulk CMOS device. The P-channel transistor 70 includes p-type diffusions in the semiconductor material of epitaxial layer 50 representing a source region 74 and drain region 76 that flank opposite sides of a channel region in the semiconductor material of epitaxial layer 50, a gate electrode 78 overlying the channel region, and a gate dielectric 80 electrically isolating the gate electrode 78 from the epitaxial layer 50. The N-channel transistor 72 includes n-type diffusions in the semiconductor material of epitaxial layer 50 that represent a source region 84 and a drain region 82 that flank opposite sides of a channel region in the semiconductor material of epitaxial layer 50, a gate electrode 86 overlying the channel region, and a gate dielectric 88 electrically isolating the gate electrode 86 from the epitaxial layer 50. Other structures, such as sidewall spacers (not shown), may be included in the construction of the P-channel transistor 70 and the N-channel transistor 72.

The conductor used to form the gate electrodes 78, 86 may be, for example, polysilicon, tungsten, or any other desired material deposited by a CVD process, etc. The source and drain regions 74, 76 and the drain and source regions 82, 84 may be formed in the semiconductor material of the epitaxial layer 50 by ion implantation of suitable dopant species having an appropriate conductivity type. The gate dielectrics 80, 88 may comprise a dielectric or insulating material like silicon dioxide, silicon oxynitride, a high-k dielectric, or any other suitable dielectric or combinations. The dielectric material constituting dielectrics 80, 88 may be between about 1 nm and about 10 nm thick, and may be formed by thermal reaction of the semiconductor material of the epitaxial layer 50 with a reactant, a CVD process, a physical vapor deposition (PVD) technique, or a combination thereof.

Processing continues to complete the semiconductor structure, including forming contacts to the gate electrodes 78, 86, source region 74, drain region 76, drain region 82, and source region 84. The contacts can be formed using any suitable technique, such as a damascene process in which an insulator is deposited and patterned to open vias, and then the vias are filled with a suitable conductive material, as understood by a person having ordinary skill in the art. The P-channel and N-channel transistors 70, 72 are coupled using the contacts with other devices on substrate 40 and peripheral devices with a multilevel interconnect structure consisting of conductive wiring and interlevel dielectrics (not shown).

With reference to FIG. 6 in which like reference numerals refer to like features in FIG. 5 and in accordance with an alternative embodiment of the present invention, the principles of the present invention may be implemented in a dual-well structure that includes the N-well 52 and P-well 54, but lacks the buried N-band 56. The actual depth of the damage layer 46, and the location of penetration depths 43, 45 with respect to the bottom of the STI regions 60 and the well junction 55, is adjusted by adjusting the thickness of the epitaxial layer 50. The thickness of the epitaxial layer 50 is advantageously selected such that the damage layer 46 lies through the N-well 52 and P-well 54 under the STI regions 60 in the dual-well structure. Alternatively, the trenches 62, 64 may be extended deeper into the epitaxial layer 50.

Advantageously, the peak atomic concentration for the implanted ions 42 in damage layer 46 is in the range of 5×10¹⁸ cm⁻³ to 5×10l¹⁹ cm⁻³ to provide the requisite level of crystalline damage in substrate 40. The ions 42 may be selected from neutral impurities that are not electrically active in silicon if the substrate 40 is composed of silicon. The boundary 52a of the N-well 52 and the boundary 54a of the P-well 54 are deeper than the deepest penetration depth 45 of the damage layer 46.

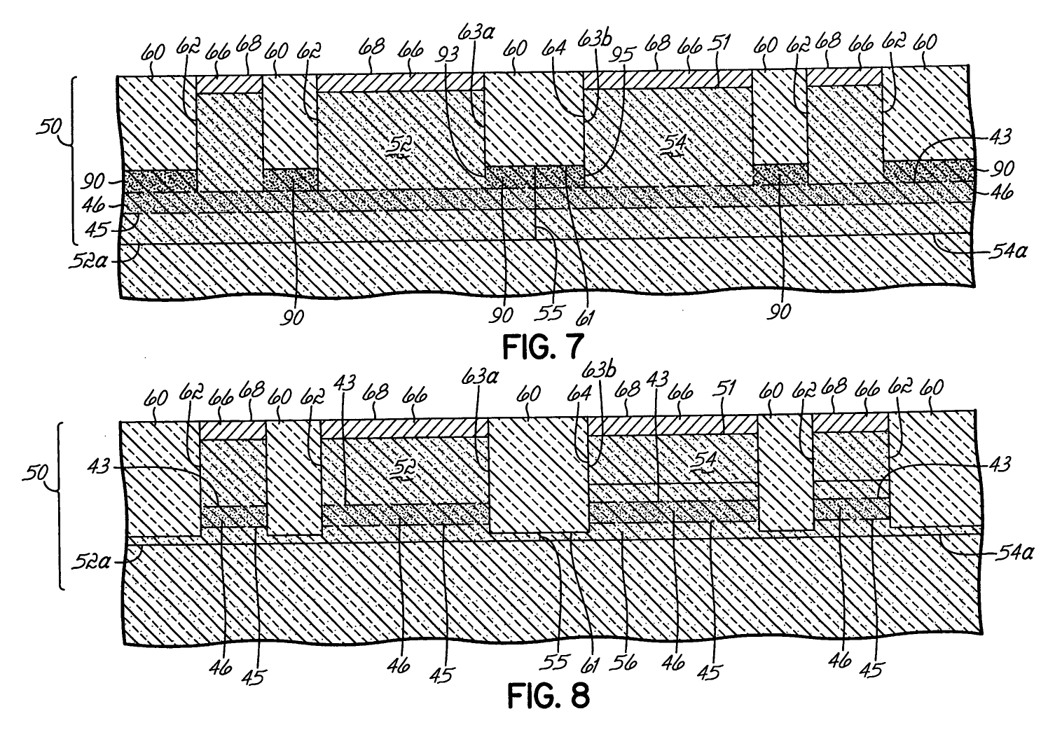

With reference to FIG. 7 in which like reference numerals refer to like features in FIG. 6 and in accordance with an alternative embodiment of the present invention, damage regions 90 may be introduced by a second ion implantation that is directed into the trenches 62, 64 of the trench pattern before the dielectric material is introduced to form the STI regions 60 and before the hard mask 66 is removed. The shallow trench pattern in the hard mask 66 operates to self-align the implanted ions with the sidewalls of the trenches 62, 64 so that the damage regions 90 have lateral edges substantially aligned in a vertical direction with the sidewalls of trenches 62, 64. In particular, the lateral edges 93, 95 of damage region 94 are aligned or registered substantially vertically with the sidewalls 63a,b of the STI region 60 in trench 64. Damage region 94 extends through the interface 55 between the N-well 52 and P-well 54.

The implanted species may advantageously be one of the implanted species used to form the damage layer 46. The ion kinetic energy is selected such that at least a portion of each of the damage regions 90 is between the damage layer 46 and the bottom of the trenches 62, 64. The ion dose used in the ion implantation process to form damage regions 90 is restricted to less than about 5×10¹⁹ cm⁻³ and, typically is within a range of about 5×10¹⁸ cm⁻³ to about 5×10¹⁹ cm⁻³.

In the dual-well construction, the damage regions 90 cooperate with the damage layer 46 to recombine carriers and advantageously limit the effect of the vertical parasitic NPN structure 22 (FIG. 1) and the lateral parasitic PNP structure 26 (FIG. 1). In particular, damage region 90 that underlies trench 64 operates to close the gap located between the base 61 of the STI region 60 in trench 64 and a top boundary of the N-band 56 with a high density of recombination centers that crosses interface 55 (FIG. 4). However, the damage regions 90 are discontinuous in a plane parallel to top surface 51.

Although the embodiment of FIG. 7 is depicted as used in conjunction with the dual-well construction of FIG. 5, the invention contemplates that the additional damage regions 90 may be used in conjunction with the triple-well construction of FIG. 4.

With reference to FIG. 8 in which like reference numerals refer to like features in FIG. 4 and in accordance with an alternative embodiment of the present invention, the penetration depths 43, 45 of the damage layer 46 may be adjusted by adjusting the kinetic energy of ions 42 (FIG. 2) such that the damage layer 46 extends laterally or horizontally above the bottom of the STI regions 60 and, in particular, the STI region 60 filling trench 64. The STI regions 60 interrupt the continuity of the damage layer 46 so that damage layer 46 is not electrically continuous (i.e., physically and electrically discontinuous). Although shown without the damage regions 90 (FIG. 7), this alternative embodiment of the present invention is not so limited. Although the embodiment of FIG. 8 is depicted as used in conjunction with the triple-well construction of FIG. 4, the invention contemplates that the change in relative depth for the damage layer 46 may be used in conjunction with the dual-well construction of FIG. 6.

The presence of the damage layer(s) 46, 90 is believed to alter the properties of the semiconductor material constituting the substrate 40 such that the process or processes responsible for latch-up are inhibited. Because the implanted ions 42 all stop within a narrow band, which is spaced away from the upper crystalline layer 48 used to grow the device epitaxial layer 50 in which the P-channel and N-channel transistors 70, 72 of the CMOS integrated circuit are located, the functionality and parameters of the P-channel and N-channel transistors 70, 72 are not degraded. Consequently, the present invention processes the substrate 40 so that the sensitivity to latch-up of the bulk CMOS P-channel and N-channel transistors 70, 72 built on the substrate 40 is reduced or eliminated because of a reduction in the transport of minority carriers between the N-well 52 and P-well 54 for dual well constructions and between the N-well 52 and N-band 56 for triple well constructions.

References herein to terms such as “vertical”, “horizontal”, etc. are made by way of example, and not by way of limitation, to establish a frame of reference. The term “horizontal” as used herein is defined as a plane parallel to the top surface 51, regardless of its actual spatial orientation. The term “vertical” refers to a direction perpendicular to the horizontal, as just defined. Terms, such as “on”, “above”, “below”, “side” (as in “sidewall”), “higher”, “lower”, “over”, “beneath” and “under”, are defined with respect to the horizontal plane. It is understood that various other frames of reference may be employed for describing the present invention without departing from the spirit and scope of the present invention.

The fabrication of the semiconductor structure herein has been described by a specific order of fabrication stages and steps. However, it is understood that the order may differ from that described. For example, the order of two or more fabrication steps may be switched relative to the order shown. Moreover, two or more fabrication steps may be conducted either concurrently or with partial concurrence. In addition, various fabrication steps may be omitted and other fabrication steps may be added. It is understood that all such variations are within the scope of the present invention. It is also understood that features of the present invention are not necessarily shown to scale in the drawings.

While the present invention has been illustrated by a description of various embodiments and while these embodiments have been described in considerable detail, it is not the intention of the applicants to restrict or in any way limit the scope of the appended claims to such detail. Additional advantages and modifications will readily appear to those skilled in the art. Thus, the invention in its broader aspects is therefore not limited to the specific details, representative apparatus and method, and illustrative example shown and described. Accordingly, departures may be made from such details without departing from the spirit or scope of applicants' general inventive concept.

What is claimed is:

1. A semiconductor structure comprising:
a substrate;
a first doped well formed in the substrate;
a second doped well formed in the substrate proximate to the first doped well; and
a damage layer formed in the substrate, the damage layer extending within the substrate to intersect the first and second doped wells.

2. The semiconductor structure of claim 1 wherein the first doped well has a first conductivity type and the second doped well has a second conductivity type.

3. The semiconductor structure of claim 2 further comprising:
a first field effect transistor with source and drain regions in the first doped well; and
a second field effect transistor with source and drain regions in the second doped well, the damage band operating to reduce latch-up of the first and second field effect transistors.

4. The semiconductor structure of claim 2 wherein the first doped well and the second doped well are coextensive along an interface, and the damage layer extends across the interface.

5. The semiconductor structure of claim 1 wherein the first and second doped wells have a first conductivity type and the substrate has a top surface, and further comprising:
a third doped well formed in the substrate, the third doped well arranged between the first doped well and the top surface, and the third doped well having a second conductivity type that differs from the first conductivity type.

6. The semiconductor structure of claim 5 further comprising:
a first field effect transistor with source and drain regions in the second doped well; and
a second field effect transistor with source and drain regions in the third doped well, the damage band operating to reduce latch-up of the first and second field effect transistors.

7. The semiconductor structure of claim 5 wherein the first doped well and the second doped well are coextensive along an interface, and the damage layer extends across the interface.

8. The semiconductor structure of claim 1 wherein the substrate has a top surface, and further comprising:
a shallow trench isolation region having a base at a shallower depth than the damage layer and sidewalls extending into the substrate from the top surface to the base; and
a damage region extending substantially between the base of the shallow trench isolation region and the damage layer, the damage region substantially registered with the sidewalls of the shallow trench isolation region.

9. The semiconductor structure of claim 8 wherein the shallow trench isolation region is formed in the substrate at a location between the first and second wells.

10. The semiconductor structure of claim 1 wherein the substrate has a top surface, and further comprising:
a shallow trench isolation region composed of a dielectric material, the shallow trench isolation region having a base and sidewalls extending into the substrate from the top surface to the base, and the damage layer intersecting the shallow trench isolation region.

11. The semiconductor structure of claim 1 wherein the damage layer further comprises a high density of recombination centers that operate to reduce minority carrier transport between the first and second wells.

12. A method of fabricating a semiconductor structure in a substrate of monocrystalline semiconductor material, the method comprising:
forming a damage layer of non-monocrystalline semiconductor material buried beneath a top surface of the substrate;
forming a first doped well that extends to a first depth in the substrate that intersects the damage layer; and
forming a second doped well that extends to a second depth in the substrate that intersects the damage layer.

13. The method of claim 12 wherein forming the damage layer further comprises:
implanting ions into the monocrystalline substrate at a kinetic energy suitable to form the buried damage layer.

14. The method of claim 13 further comprising:
growing an epitaxial layer on the substrate after the damage layer is formed.

15. The method of claim 14 wherein implanting ions further comprises:
selecting the kinetic energy to retain a crystalline layer suitable for growth of the epitaxial layer.

16. The method of claim 14 further comprising:
forming source and drain regions of a first field effect transistor in the epitaxial layer; and
forming source and drain regions of a second field effect transistor in the epitaxial layer.

17. The method of claim 12 wherein the first doped well has a first conductivity type and the second doped well has a second conductivity type, and further comprising:
forming source and drain regions of a first field effect transistor in the first doped well; and
forming source and drain regions of a second field effect transistor in the second doped well.

18. The method of claim 11 wherein the first doped well and the second doped well have a first conductivity type and the substrate has a top surface, and further comprising:
forming a third doped well of a second conductivity type that differs from the first conductivity type in the substrate between the first doped well and the top surface.

19. The method of claim 18 further comprising:
forming source and drain regions of a first field effect transistor in the second doped well; and
forming source and drain regions of a second field effect transistor in the third doped well.

20. The method of claim 12 further comprising:
forming a trench having sidewalls that extend into the substrate at a location between the first and second doped wells; and
filling the trench with a dielectric material.

21. The method of claim 20 further comprising:
forming a damage region substantially registered with the sidewalls of the trench and extending substantially between a base of the trench and the damage layer before the trench is filled with the dielectric material.

22. The method of claim 20 wherein forming the trench further comprises:
extending the trench to a depth that penetrates through the damage layer.
